(19) United States
(12) Patent Application Publication
(10) Pub. No.: US 2016/0225881 A1
(43) Pub. Date: Aug. 4, 2016

(54) SILICON GERMANIUM FINFET FORMATION

(71) Applicant: QUALCOMM Incorporated, San Diego, CA (US)

(72) Inventors: Jeffrey Junhao XU, San Diego, CA (US); Choh Fei YEAP, San Diego, CA (US)

(21) Appl. No.: 15/097,127

(22) Filed: Apr. 12, 2016

Related U.S. Application Data
(62) Division of application No. 14/269,828, filed on May 5, 2014.
(60) Provisional application No. 61/908,003, filed on Nov. 22, 2013.

(51) Int. Cl. H01L 29/66; H01L 21/324; H01L 29/06; H01L 21/265; H01L 29/161; H01L 29/10

(52) U.S. Cl. CPC H01L 29/66803; H01L 29/161; H01L 29/1054; H01L 29/0653; H01L 21/26513; H01L 21/26586; H01L 21/324

(57) ABSTRACT

Methods for fabricating a fin in a fin field effect transistor (FinFET), include exposing a single crystal fin structure coupled to a substrate of the FinFET. The single crystal fin structure is of a first material. The method further includes implanting a second material into the exposed single crystal fin structure at a first temperature. The first temperature reduces amorphization of the single crystal fin structure. The implanted single crystal fin structure comprises at least 20% of the first material. The method also includes annealing the implanted fin structure at a second temperature. The second temperature reduces crystal defects in the implanted fin structure to form the fin.

### CROSS-REFERENCE TO RELATED APPLICATIONS

This application is a divisional of U.S. patent application Ser. No. 14/269,828, entitled “SILICON GERMANIUM FINFET FORMATION,” filed on May 5, 2014, which claims the benefit under 35 U.S.C. §119(e) to U.S. Provisional Patent Application No. 61/908,003, entitled “SILICON GERMANIUM FINFET FORMATION,” filed on Nov. 22, 2013, the disclosures of which are expressly incorporated by reference herein in their entireties.

### BACKGROUND

1. Field

Aspects of the present disclosure relate to semiconductor devices, and more particularly to silicon germanium (SiGe) use in field effect transistor (FET) structures having fin (FinFET) channels.

2. Background

SiGe has been widely reviewed as a promising material for p-channel metal-oxide-semiconductor (PMOS) devices. SiGe has a compressive strain that increases the hole mobility in the material. In standard FET geometries, imparting a strain in semiconductor chip regions, such as the source and drain regions of a FET, is common. In FinFET structures, however, the volume of the fin available for strain engineering is small. As fin geometries are reduced, such as in 10 nanometer device designs, fabrication of SiGe fins is expensive and difficult to achieve.

### SUMMARY

A method for fabricating a fin in a fin field effect transistor (FinFET) in includes exposing a single crystal fin structure coupled to a substrate of the FinFET. The single crystal fin structure is made of a first material. The method also includes implanting a second material into an exposed portion of the single crystal fin structure at a first temperature. The first temperature reduces amorphization of the single crystal fin structure. The implanted single crystal fin structure includes at least 20% of the first material. The method also includes annealing the implanted fin structure at a second temperature that reduces crystal defects in the implanted fin structure to form the fin.

A silicon-germanium (SiGe) fin field effect transistor (FinFET) includes a substrate and a single crystal fin structure comprising at least 20% implanted germanium. The single crystal fin structure is coupled to the substrate with a graded junction.

A silicon-germanium (SiGe) fin field effect transistor (FinFET) includes means for supporting a current channel and means for carrying current comprising at least 20% implanted germanium. The carrying means is coupled to the supporting means with a graded junction.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIGS. 1A-1D illustrate side views of a FinFET semiconductor device.

FIG. 2 illustrates a side view of the fin structures of a FinFET semiconductor device in accordance with one aspect of the present disclosure.

FIG. 3 illustrates etching isolation material instead of etching or removing the fin structure.

FIG. 4 illustrates implanting dopant atoms into the fin structures of a FinFET semiconductor device in accordance with one aspect of the present disclosure.

FIG. 5 illustrates a side view of a doped fin structure in accordance with one aspect of the present disclosure.

FIG. 6 illustrates the growth of an oxide around the doped fin structure in accordance with one aspect of the present disclosure.

FIG. 7 illustrates removal of the oxide from the doped fin structure to produce a final fin structure in accordance with one aspect of the present disclosure.

FIG. 8 is a process flow diagram illustrating a method for fabricating a silicon-germanium (SiGe) fin in a fin field effect transistor (FinFET) according to an aspect of the present disclosure.

FIG. 9 is a block diagram showing an exemplary wireless communication system in which a configuration of the disclosure may be advantageously employed.

FIG. 10 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

A high mobility conduction channel is desirable for high performance transistors. Material selection and strain engineering are design features that are used to alter the mobility of charge carriers in the channel of transistors. In metal-oxide-semiconductor (MOS) field effect transistors (MOSFETs), strain engineering is used, but in fin-based structures (FinFETs), the use of strained materials is challenging. There are more free surfaces in FinFET structures, and the source/drain volume available for strain engineering is small compared to other FET geometries and techniques.

Silicon germanium (SiGe) is considered as a leading candidate for 10 nanometer and smaller PMOS devices. SiGe fin formation in the related art utilizes an etch or recess of the Si fin followed by epitaxial growth of SiGe in the recess. A chemical-mechanical planarization (CMP) process is often used to remove overgrown SiGe above the shallow trench isolation (STI) material to form the SiGe fins. The cost of this related art process is high, resulting in high cost FinFET devices.

Further, although a SiGe fin grown on a silicon template often possesses uniaxial compressive stress along the fin length, epitaxially grown SiGe uses a thermal anneal at temperatures exceeding 900 degrees Centigrade to cure epitaxial growth defects. This anneal will likely relax the uniaxial stress in the SiGe, which may reduce the hole mobility in the SiGe channel.

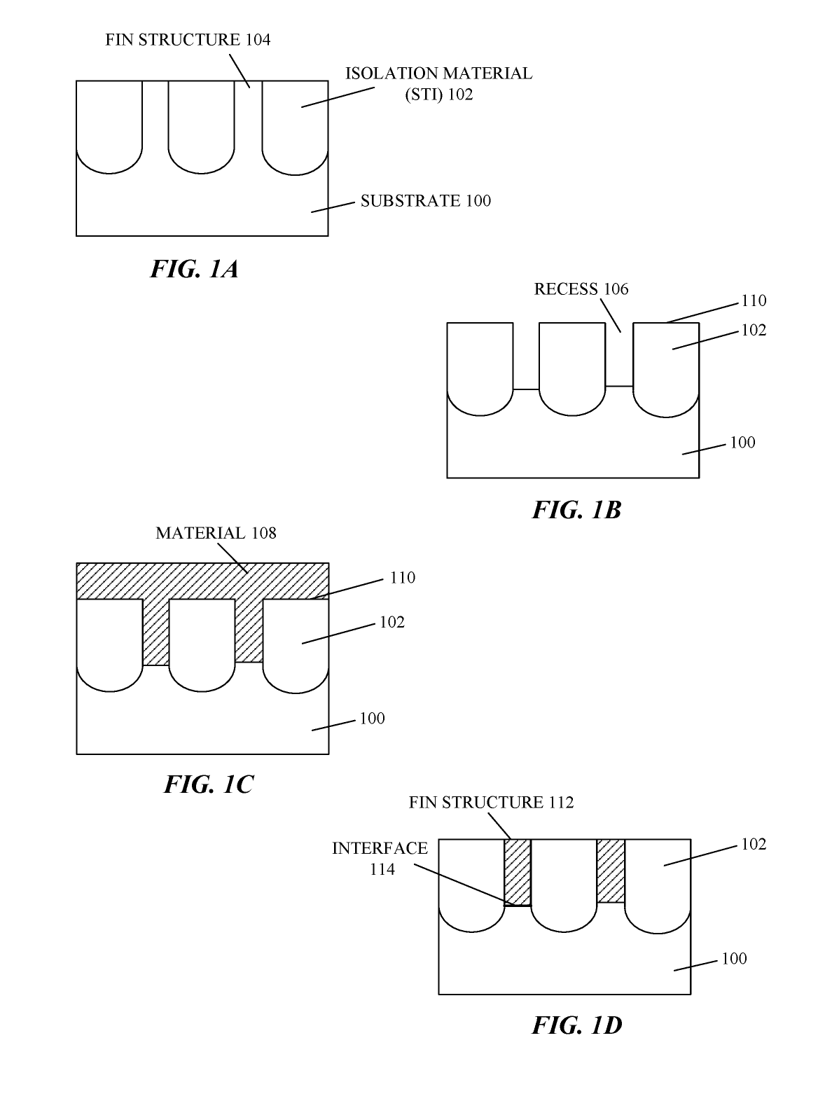

FIGS. 1A-1D illustrate side views of a FinFET semiconductor device. FIG. 1A shows a substrate 100, isolation material 102, and fin structures 104. The substrate 100 may be a semiconductor material, such as silicon. The isolation material 102 may be a shallow trench isolation (STI) material, such as silicon oxide or silicon nitride, or other materials. The fin structures 104 may be crystalline, and may be a part of a single crystal structure along with the substrate 100.

In related art approaches, the fin structures 104 are etched or otherwise removed to create a recess 106 as shown in FIG. 1B. The isolation material 102 serves as the form for the recess 106. In FIG. 1C, a material 108 is grown within the recesses 106, and may be grown over a surface 110 of the isolation material 102. The overgrowth of the material 108 is removed via etching or polishing (e.g., CMP), to create the fin structure 112 as shown in FIG. 1D. The material 108 may be SiGe. When the material 108 is SiGe, the growth across the substrate 100 and in the recess 106 is of a uniform percentage of germanium, which limits the number of voltage thresholds of the devices on the substrate 100 using the material 108. Further, an interface 114 may have an abrupt boundary, which may limit the minimum size of the fin structure 112.

Once the fin structure 104 is formed as shown in FIG. 1D, the fin structure 104 is annealed to reduce growth defects within the fin structure 104. This annealing may take place at elevated temperatures, such as temperatures over 900 degrees Centigrade, which may amorphize the fin structure 112 and/or relax the compressive strain along the length of the fin structure 112. Reducing or relaxing the compressive strain along the fin structure 112 reduces the carrier mobility in the fin structure 112, and the advantages of using the material 108 in the fin structure 112 are reduced as a result.

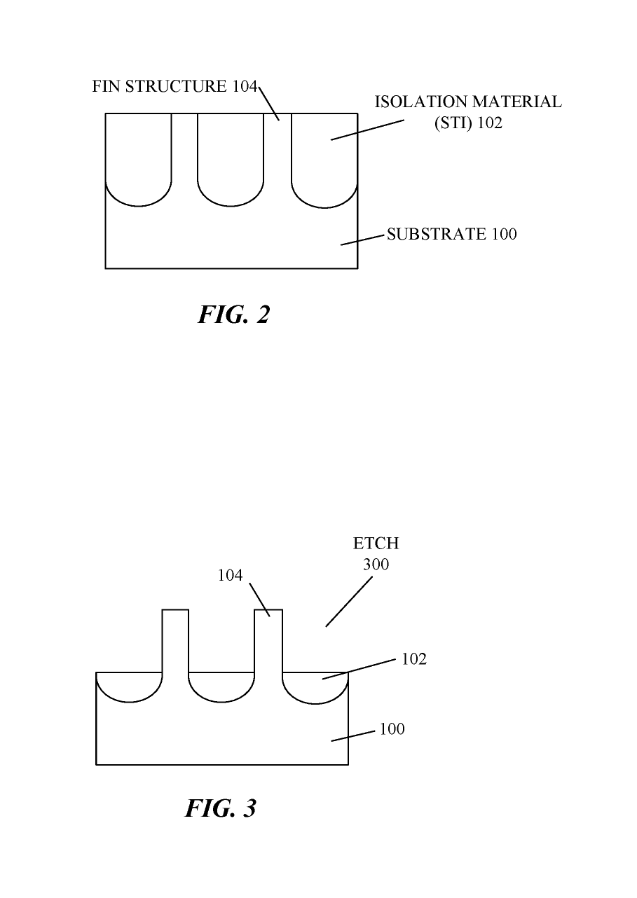

FIGS. 2 through 7 illustrate side views of a FinFET semiconductor device in accordance with one or more aspects of the present disclosure. FIG. 2 illustrates a side view of the fin structures of a FinFET semiconductor device in accordance with one aspect of the present disclosure. In this configuration, the fin structures 104 are shown as single crystal structures formed as part of the substrate 100, with the isolation material 102 between the fin structures 104. The substrate 100 may be a semiconductor material, such as silicon. The isolation material 102 may be a shallow trench isolation (STI) material, such as silicon oxide or silicon nitride, or other like isolation layer.

FIG. 3 illustrates an etch 300, that etches the isolation material 102. In this configuration, the isolation material is etched, rather than etching or removing the fin structure 104, as shown in FIG. 1B. The etch 300 may be performed using a hydrofluoric acid (HF) etch, or may be performed using a chemical wet/vapor etch (CWE) process using other etchants or other like etch process.

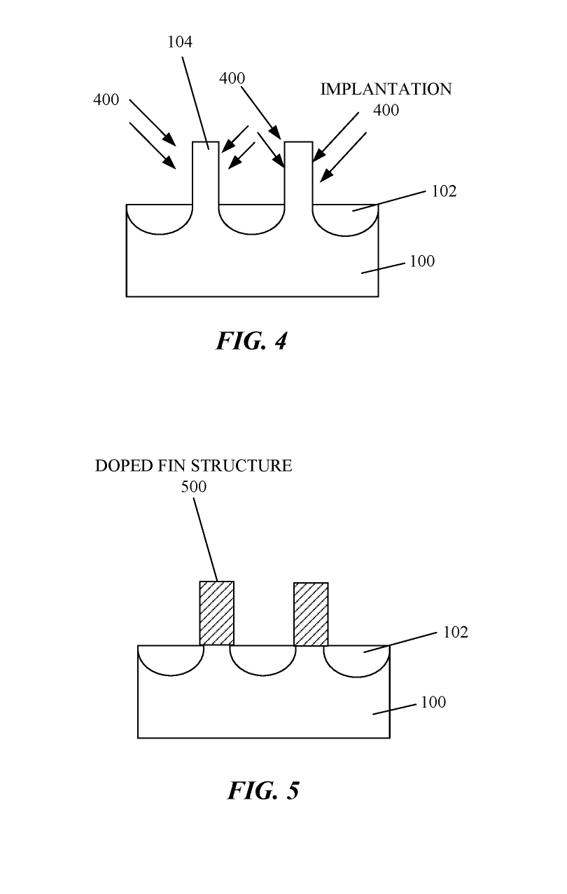

FIG. 4 illustrates implanting dopant atoms into the fin structures of a FinFET semiconductor device in accordance with one aspect of the present disclosure. In this aspect of the disclosure, an implantation 400 implants the dopant atoms into the fin structures 104. The implantation 400, in this aspect of the present disclosure, implants germanium into the fin structures 104. The implantation may be performed to form a compound semiconductor material in the fin structure 112, rather than to dope the fin structure 112. For example, germanium is used when the implantation 400 may implant any percentage of germanium in the fin structure 112, (e.g., from 1% to 99%). Germanium may be implanted at a percentage of at least 20%. Although described with respect to germanium, other materials may be implanted at other percentages without departing from the scope of the present disclosure. In one example configuration, a first atomic radius of the first material is different from a second atomic radius of the second material by less than fifteen percent. Further, although described with respect to a binary compound semiconductor, tertiary, quaternary, or other combinations of several materials (e.g., semiconductor, conductive or insulative materials) may be implanted into the fin structure 112 without departing from the scope of the present disclosure. In one configuration, a third material is implanted into the fin at a third temperature that reduces amorphization of the single crystal fin.

The implantation 400 may be performed at an angle that is not perpendicular or parallel to the surfaces of the fin structures 104. Further, the amount of the implantation 400 of the specified materials (e.g., germanium) may be controlled for various ones of the fin structures 104 to control the percentage of dopant atoms in each of the fin structures 104. This aspect of the present disclosure may allow for a larger number of voltage thresholds for the devices employing the fin structures 104 on a given substrate 100. The implantation 400 may be performed at an elevated temperature (˜600° C.) to reduce the possibility of amorphization of the fin structure 104.

FIG. 5 illustrates a side view of a doped fin structure in accordance with one aspect of the present disclosure. In FIG. 5, a doped fin structure 500 is shown in which the doped fin structure 500 is slightly larger than the fin structure 104, and overlaps the isolation material 102. Because the implantation 400 has added material (e.g., the implanted material from the implantation) into the fin structure 104, the doped fin structure 500 is shown slightly larger than the fin structure 104.

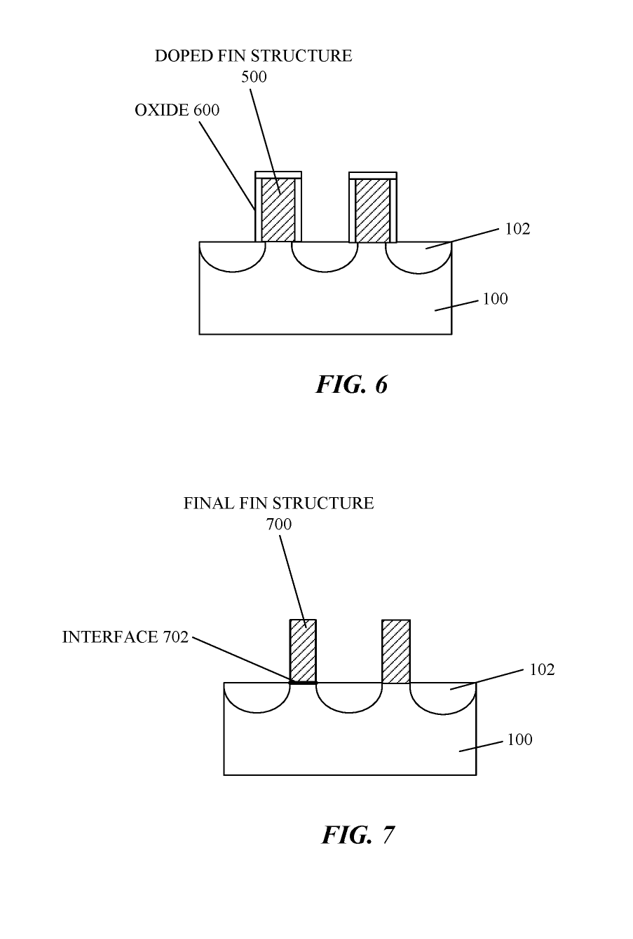

FIG. 6 illustrates the growth of an oxide around the doped fin structure in accordance with one aspect of the present disclosure. Representatively, an oxide 600 is grown around the doped fin structure 500. In an aspect of the present disclosure, when the doped fin structure 500 is annealed, the presence of oxygen in the anneal process oxidizes with some of the silicon in the doped fin structure 500 (e.g., a germanium-doped silicon fin structure). This creates the oxide 600, which in an aspect of the present disclosure is silicon oxide. The anneal, in this aspect of the present disclosure, takes place at a high temperature, which may be at approximately 1000-1300 degrees Centigrade, which forms the oxide 600 and reduces the crystal lattice defects (e.g., stacking defects, implantation damage, etc.) in the doped fin structure 500.

FIG. 7 illustrates removal of the oxide from the doped fin structure to produce a final fin structure in accordance with one aspect of the present disclosure. In particular, the oxide 600 is removed from the doped fin structure 500 to produce a final fin structure 700. Now that some material has been removed from the doped fin structure 500 through the creation of the oxide 600 and through the etch process to remove the oxide 600, the final fin structure 700 is shown as further aligned with the original width of the fin structure 104. Further, an interface 702 is less abrupt than the interface 114 shown in FIGS. 1A to 1D because it was formed from a single crystal structure emanating from the substrate 100.

The anneal of FIG. 6 also drives dopant atoms into the substrate 100, which reduces the heterogeneous nature of the interface 702. In an aspect of the present disclosure, the final fin structure 700 is self-aligned to an original version of the fin structure 104. Further, as described above, the concentration of dopant material, e.g., germanium, in the final fin structure 700 can be controlled using different doses of dopant material during the implantation 400. As such, multiple dopant concentrations for different type of devices on the same substrate 100 can be realized in an aspect of the present disclosure. Further, the present disclosure provides a final fin structure that is less expensive to produce than that of conventional SiGe FinFETs using epitaxial growth.

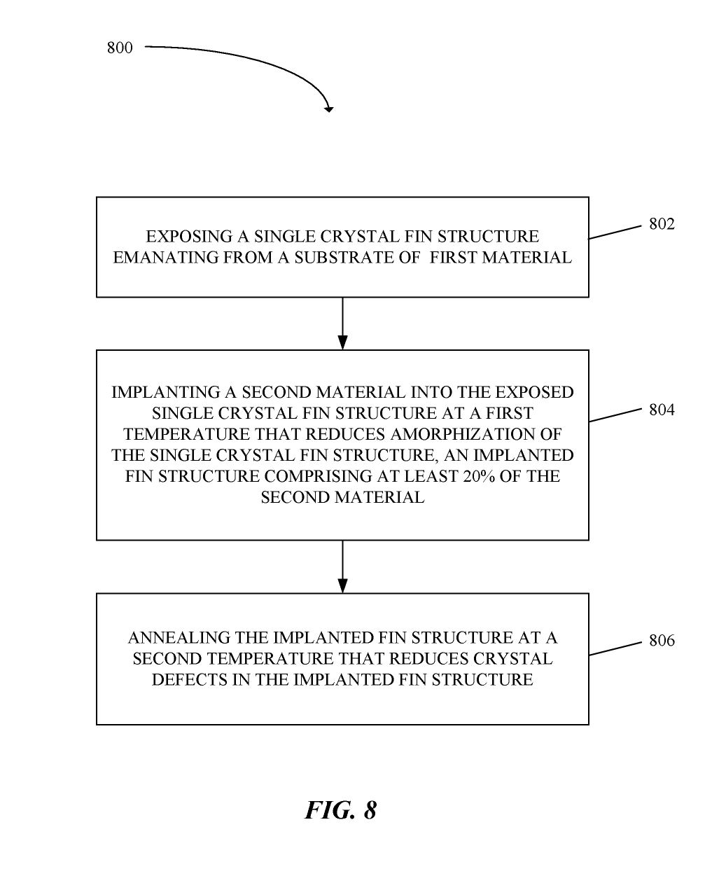

FIG. 8 is a process flow diagram illustrating a method 800 for fabricating a fin field effect transistor (FinFET) device according to an aspect of the present disclosure. In block 802 a single crystal fin structure emanating from a substrate of a first material is exposed. For example, as shown in FIG. 3, an etch 300 is performed to etch the isolation material. In block 804, a second material is implanted into the exposed single crystal fin structure at a first temperature. For example,

FIG. 4 illustrates an implantation 400 of dopant atoms into the fin structure 104 to form an implanted fin structure. The first temperature is selected to reduce amorphization of the single crystal fin structure. In this example, the implantation 400 is performed at an elevated temperature (˜600° C.) to reduce the possibility of amorphization of the fin structure 104.

In block 806, the implanted fin structure is annealed at a second temperature, as shown in FIG. 6. The second temperature reduces crystal defects in the implanted fin structure. For example, the anneal, in this aspect of the present disclosure, takes place at a high temperature, which may be at approximately 1000-1300 degrees Centigrade. The anneal at the second temperature forms the oxide 600 and reduces the crystal lattice defects (e.g., stacking defects, implantation damage, etc.) in the doped fin structure 500.

According to a further aspect of the present disclosure, a silicon-germanium (SiGe) fin field effect transistor (FinFET) is described. In one configuration, the FinFET includes means for supporting a current channel. The supporting means may be substrate 100. The FinFET also includes means for carrying current comprising implanted germanium. The current carrying means may be the final fin structure 700. In another aspect, the aforementioned means may be any module or any apparatus configured to perform the functions recited by the aforementioned means.

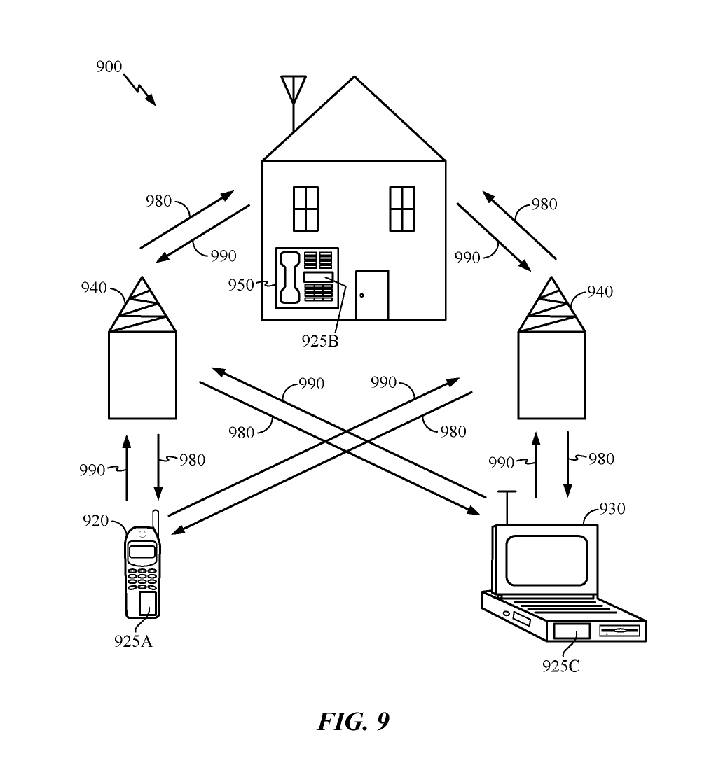

FIG. 9 is a block diagram showing an exemplary wireless communication system 900 in which an aspect of the disclosure may be advantageously employed. For purposes of illustration, FIG. 9 shows three remote units 920, 930, and 950 and two base stations 940. It will be recognized that wireless communication systems may have many more remote units and base stations. Remote units 920, 930, and 950 include IC devices 925A, 925C, and 925B that include the disclosed FinFET devices. It will be recognized that other devices may also include the disclosed FinFET devices, such as the base stations, switching devices, and network equipment. FIG. 9 shows forward link signals 980 from the base station 940 to the remote units 920, 930, and 950 and reverse link signals 990 from the remote units 920, 930, and 950 to base stations 940.

In FIG. 9, remote unit 920 is shown as a mobile telephone, remote unit 930 is shown as a portable computer, and remote unit 950 is shown as a fixed location remote unit in a wireless local loop system. For example, a remote unit may be a mobile phone, a hand-held personal communication systems (PCS) unit, a portable data unit such as a personal data assistant, a GPS enabled device, a navigation device, a set top box, a music player, a video player, an entertainment unit, a fixed location data unit such as a meter reading equipment, or other devices that store or retrieve data or computer instructions, or combinations thereof. Although FIG. 9 illustrates remote units according to the aspects of the disclosure, the disclosure is not limited to these exemplary illustrated units. Aspects of the disclosure may be suitably employed in many devices, which include the disclosed FinFET devices.

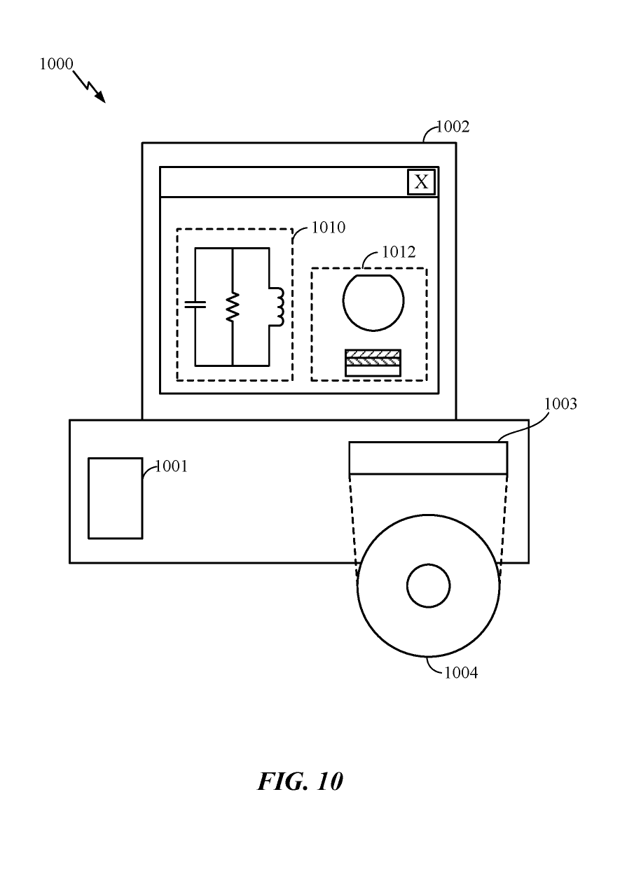

FIG. 10 is a block diagram illustrating a design workstation used for circuit, layout, and logic design of a semiconductor component, such as the FinFET devices disclosed above. A design workstation 1000 includes a hard disk 1001 containing operating system software, support files, and design software such as Cadence or OrCAD. The design workstation 1000 also includes a display 1002 to facilitate design of a circuit 1010 or a semiconductor component 1012 such as a FinFET device. A storage medium 1004 is provided for tangibly storing the design of the circuit 1010 or the semiconductor component 1012. The design of the circuit 1010 or the semiconductor component 1012 may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1004 facilitates the design of the circuit 1010 or the semiconductor component 1012 by decreasing the number of processes for designing semiconductor wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A method for fabricating a fin in a fin field effect transistor (FinFET), comprising:
exposing a single crystal fin structure emanating from a substrate of the FinFET, the single crystal fin structure being of a first material of the substrate;
implanting a second material into an exposed portion of the single crystal fin structure at a first temperature that reduces amorphization of the single crystal fin structure, the implanted single crystal fin structure comprising at least 20% of the second material; and
annealing the implanted fin structure at a second temperature that reduces crystal defects in the implanted fin structure.

2. The method of claim 1, in which the substrate comprises silicon.

3. The method of claim 1, in which the second material is germanium (Ge).

4. The method of claim 1, in which the implanting occurs at an angle that is not perpendicular to any surface of the fin.

5. The method of claim 1, in which the first temperature is higher than the second temperature.

6. The method of claim 1, in which a first atomic radius of the first material is different from a second atomic radius of the second material by less than fifteen percent.

7. The method of claim 1, further comprising implanting a third material into the exposed portion of the single crystal fin structure at a third temperature, in which the third temperature reduces amorphization of the single crystal fin structure.

8. The method of claim 1, further comprising integrating the FinFET into a mobile phone, a set top box, a music player, a video player, an entertainment unit, a navigation device, a computer, a hand-held personal communication systems (PCS) unit, a portable data unit, and/or a fixed location data unit.

9. A method for fabricating a silicon-germanium (SiGe) fin field effect transistor (FinFET), comprising:
etching a portion of an isolation layer on a substrate to expose a fin of a single crystal structure emanating from the substrate of a first material;
implanting a second material into the fin at a first temperature that reduces amorphization of the fin to provide an implanted fin structure comprising at least 20% of the second material; and
annealing the implanted fin structure at a second temperature that reduces crystal defects in the implanted fin structure.

10. The method of claim 9, in which the substrate comprises silicon.

11. The method of claim 9, in which the second material is germanium (Ge).

12. The method of claim 9, in which implanting occurs at an angle that is not perpendicular to any surface of the fin.

13. The method of claim 9, in which the first temperature is higher than the second temperature.

14. The method of claim 9, in which a first atomic radius of the first material is different from a second atomic radius of the second material by less than fifteen percent.

15. The method of claim 9, further comprising implanting a third material into the fin at a third temperature, in which the third temperature reduces amorphization of the fin.

16. The method of claim 9, further comprising integrating the FinFET into a mobile phone, a set top box, a music player, a video player, an entertainment unit, a navigation device, a computer, a hand-held personal communication systems (PCS) unit, a portable data unit, and/or a fixed location data unit.

17. A method for fabricating a silicon-germanium (SiGe) fin in a fin field effect transistor (FinFET), comprising:
a step for exposing a single crystal fin structure emanating from a substrate, the single crystal fin structure being of a first material of the substrate;
a step for implanting a second material into an exposed portion of the single crystal fin structure at a first temperature that reduces amorphization of the single crystal fin structure, the implanted single crystal fin structure comprising at least 20% of the second material; and
a step for annealing the implanted fin structure at a second temperature that reduces crystal defects in the implanted fin structure.

18. The method of claim 17, in which the second material is germanium (Ge).

19. The method of claim 17, in which the step for implanting occurs at an angle that is not perpendicular to any surface of the single crystal fin structure.

20. The method of claim 17, further comprising a step for integrating the FinFET into a mobile phone, a set top box, a music player, a video player, an entertainment unit, a navigation device, a computer, a hand-held personal communication systems (PCS) unit, a portable data unit, and/or a fixed location data unit.
